(19) United States
(12) Patent Application Publication
(10) Pub. No.: US 2025/0125585 A1
(43) Pub. Date: Apr. 17, 2025

(54) ANGULAR TUNING OF OPTICAL RESONANCE IN A VERTICALLY INTEGRATED SPATIALLY-PERIODIC MEDIUM AND OPERATION OF VECSELS EMPLOYING SUCH ANGULAR TUNING

(71) Applicant: Arizona Board of Regents on behalf of the University of Arizona, Tucson, AZ (US)

(72) Inventors: Jerome Moloney, Tucson, AZ (US); Simon Tsaoussis, Tucson, AZ (US)

(21) Appl. No.: 18/750,159

(22) Filed: Jun. 21, 2024

Related U.S. Application Data
(60) Provisional application No. 63/522,778, filed on Jun. 23, 2023.

(51) Int. Cl. H01S 5/183; H01S 5/04; H01S 5/065; H01S 5/22

(52) U.S. Cl. CPC H01S 5/18358; H01S 5/041; H01S 5/0657; H01S 5/2228

(57) ABSTRACT

A spectral characteristic of operation of a laser source containing, within its V-cavity, a gain medium structured to include a stack of substantially spatially-periodically distributed semiconductor material, is being tuned or varied by reshaping the V-cavity due to repositioning/reorienting the outermost reflectors limiting such cavity. When laser source configured as a VECSEL includes multiple pairs of the outermost reflectors (each pair defining a corresponding constituent V-cavity having the corresponding optical resonance), these multiple V-cavities are coupled at least through the carrier distributions within the common gain medium that such cavities share. Different modes of operation of such laser source.

### CROSS-REFERENCE TO RELATED APPLICATIONS

This US patent application claims priority from and benefit of the U.S. Provisional Patent Application No. 63/522,778 filed on Jun. 23, 2023, the entire disclosure of which is incorporated by reference herein.

### STATEMENT CONCERNING FEDERALLY SPONSORED RESEARCH AND DEVELOPMENT

This invention was made with government support under Grant No. FA9550-17-1-0246 awarded by Air Force Office of Scientific Research. The government has certain rights in the invention.

### TECHNICAL FIELD

Implementations of the invention generally relate to mode-locked vertical external cavity semiconductor lasers (VECSELs) driven far from equilibrium and, in particular, to multiple co-existing mode-locked optically-pumped V-cavity VECSELs sourced by a common gain medium and operating as independent light-generating channels at angle-controlled distinct corresponding wavelengths.

### RELATED ART

Ultrafast mode-locked laser oscillators, pervasive in modern day applications, range from all-fiber based MHz repetition rate oscillators using Saturable Absorbers (SAs), and nonlinear phenomena, to hundreds of GHz repetition rate micro-ring resonators. There are various applications for these ultra-fast oscillators, which require tuneability of wavelength, multiple mode locked oscillator sources, or benefit from multi-GHz repetition rates with large peak powers such as multi photon microscopy, multi-comb spectroscopy, and pump-probe microscopy. Optically-pumped VECSELs, which fill a niche with repetition rates between fiber and micro-ring systems, conventionally utilize broadband semiconductor gain media to produce frequency tunable, extremely low noise (see, for example, A. Garnache, et al., in Opt. Express 15, 9403-9417; 2007), robust, and low-cost mode-locked laser oscillator solutions. VECSELs make ideal testbeds for studying nonlinear systems driven far from equilibrium.

The schematic of FIG. 1A depicts the conventional VECSEL arrangement containing a target material structure 100 that contains an arrangement of the pre-determined semiconductor material—for example, layers of pre-determined semiconductor material; in one non-limiting case—such layers configured as Quantum Wells, QWs-that is spatially periodically, as a stack, embedded in a bulk 3D host semiconductor medium. The material structure 100 would be placed inside the liner laser cavity formed by first and second reflectors (not shown for simplicity of illustration). In such a conventionally-structured VECSEL the axially supported by the VESCELs structure optical waves propagate and interfere in the longitudinal/axial direction within the VECSEL cavity. In this well-known case, at normal incidence to the cavity reflectors (which, in the case of the structure of FIG. 1A, are substantially parallel to the planes of the spatially periodic layers of the target material structure 100), the first and second interfering with one another optical waves exhibit an interference spacing of λ/λn (n being a refractive index of the relevant medium), and the resultant Fabry-Perot microcavity supports a standing wave that can greatly enhance the single pass gain if the spatially-periodically distributed layers configured as QWs are placed at the antinodes of the standing wave (the situation referred to as Resonant Periodic Gain, or RPG). The axis 120 represents a normal drawn to the surfaces of the layers of the material structure 100, and in the case of FIG. 1A substantially coincides with the optical axis of the linear cavity. The inset to FIG. 1A illustrates the cross-section of an example of a modal distribution of light generated by the VECSEL laser source with the gain medium configured according to the structure 100.

The related art is silent, however, with respect to how interference of optical waves may be affected by a change or variation of the angle of incidence of plane optical waves or confined optical beams and, in particular, how the change of variation of the angle (at which optical waves propagate within the VECSEL cavity with respect to the planes of spatially-periodic material layers) affects the performance of the VESCEL device.

Implementations of the idea of the invention discussed below address this question and provide structures exploiting novel VECSEL cavity geometries configured to generate independent pulse trains that still maintain a high degree of mutual coherence.

### SUMMARY OF THE INVENTION

Implementations of the idea of the invention manifest in a coupled cavity laser source, in which multiple (in the discussed non-limiting example-two) optical V-cavities spatially overlap on or at a common (shared) semiconductor gain medium. These multiple laser cavities may be individually (independently from one another) mode-locked with the used separate semiconductor saturable absorber mirrors (SESAMs). The disclosure presented below discusses numeric and experimental investigate of the complex dynamics resulting from the gain competition between the so-coupled V-cavity based lasers in search for regimes of stable mode locked operation. The coupled cavity laser source design provides a high level of coherence between the respectively corresponding pulse trains due to rejection of pump-induced noise that is common to all of the multiple coupled laser cavities, while still allowing for the ability to easily adjust the relative repetition rates. (In addition, the multiple trains of optical pulses generated by such laser source-when the laser source operates in a pulsed regime—may, in at least one specific case, not overlap on the gain medium: in such specific case, the overall system does not exhibit the dynamics discussed below.) In structuring the embodiments of the laser source, different angles of incidence of intracavity light on the semiconductor gain medium are utilized to minimize gain competition and to enable operation at multiple respectively corresponding different wavelengths. The use of multiple external laser cavities enables additional flexibility to control the relative repetition rate of the multiple pulse trains generated by the laser source. As the skilled artisan will appreciate, microscopic modeling of this coupled cavity system requires that one move beyond the paraxial assumption and solve the Maxwell-Semiconductor Bloch (MSBE) equations taking account of higher order transverse spatial gratings encoded in the gain medium. Depending on the angle of incidence of a particular branch of the laser source cavity, the expansion of the SBE in higher order Fourier modes exhibits a natural cutoff. (Notably, related art was limited to a Fourier mode expansion assuming paraxial small angles and suggested that these grating terms act to further stabilize the mode-locking.

Embodiments of the invention provide a laser source that includes a gain medium and an optical apparatus enclosing such gain medium. The gain medium has a gain spectrum characterized by a gain spectrum bandwidth and includes multiple layers of substantially spatially-periodically spaced layers of a chosen semiconductor material. In at least one—and, generally, in every-implementation of the laser source, the multiple layers of the chosen semiconductor material may be configured as quantum wells (QWs). The optical apparatus includes at least a first optical reflector, a second optical reflector, and a third optical reflector (which, aggregately, form a first optical resonator having a first resonator axis and incorporating the gain medium therein when the first optical reflector is in a first initial position and the second optical reflector is in a second initial position, and which aggregately form a second optical resonator having a second resonator axis and incorporating the gain medium therein when the first optical reflector is in a first changed position and the second optical reflector is in a second changed position). The first and second optical resonators share the third reflector. The first resonator axis is tilted with respect to a normal drawn to the multiple layers by a first tilt angle while the second optical axis is tilted with respect to said normal by a second tilt angle that is different from the first tilt angle. Substantially in every implementation of the laser source, the optical apparatus is configured to transform the first optical resonator into the second optical resonator by repositioning and/or reorienting the first and second reflectors. (Optionally—and substantially in every implementation—the laser source may be additionally equipped with a fourth optical reflector and a fifth optical reflector that are optically connected through the gain medium and the third optical reflector to define the second optical resonator, the laser source configured to simultaneously generate optical radiation at a first central wavelength corresponding to the first optical resonator and at a second wavelength corresponding to the second optical resonator.)

In at least one specific case, the laser source may additionally contain a pump source that is in operable communication with the gain medium and that is configured to pump energy to the gain medium to produce excited-state carriers in the chosen semiconductor material. Alternatively or in addition—and substantially in every implementation of the invention-a first optical cavity length of the first optical resonator may be substantially equal to a second optical cavity length of the second optical resonator. Alternatively or in addition, substantially every embodiment of the laser source may be configured to satisfy at least one of the following conditions: the third optical reflector is separated from each of the first and second optical reflectors by the gain medium; the third optical reflector is in contact with or comprises a part of the gain medium; at least one of the first and second optical reflectors is separated from the gain medium with a corresponding free-space gap; at least one of the first and second optical reflectors is substantially perpendicular to a corresponding axis of the first and second resonator axes; and each of the first optical resonator and the second optical resonator is dimensioned to define a corresponding V-cavity of the laser source. Preferably, and substantially in every embodiment, the laser source may be dimensioned to generate (i) a first standing optical wave within the gain medium when the first, second, and third optical reflectors form the first optical resonator, wherein the first standing optical wave is characterized by first antinodes that are located at the substantially periodically spaced multiple layers, and (ii) to generate a second standing optical wave within the gain medium when the first, second, and third optical reflectors form the second optical resonator, wherein the second standing optical wave is characterized by second antinodes located at the substantially periodically spaced multiple layers. Optionally, at substantially in every implementation, the laser source may include at least one mode-lock element disposed in optical communication with the gain medium and configured to define mode-locked pulses of laser radiation generated inside a corresponding of the first and second optical resonators when said pump energy is delivered to the gain medium. (When the mode-lock element is missing, the embodiment of the laser source is configured to generate the CW optical output. When the mode-lock element is present, at may include at least one of a semiconductor saturable absorber mirror element, a self-phase modulation Kerr lens element, and an active modulation element.) In at least one specific case, the laser source is configured to operate as a VECSEL that has multiple spectral channels: in either of (a) a continuous-wave regime and (b) a pulsed regime (here, each of said multiple spectral channels has a corresponding central wavelength and a corresponding spectral bandwidth that is narrower than the bandwidth of the gain spectrum. (When the laser source is configured to operate as said VESCEL in the pulsed regime, the laser source may be configured to have a first repetition rate of pulses generated in a first of the multiple spectral channels be adjustable substantially independently from adjusting a second repetition rate of pulses generated in a second of the multiple spectral channels. Here, the first of the multiple spectral channels corresponds to the first optical resonator of the VECSEL and the second spectral channel corresponds to the second optical resonator of said VECSEL.) An embodiment of the laser source may be configured to have a first central wavelength corresponding to the first optical resonator to be shorter than a second central wavelength corresponding to the second optical resonator when the first tilt angle is smaller than the second tilt angle. Optionally, the gain medium includes a layer of Transition Metal Dichalcogenide (TMDC) material.

Embodiments of the invention also provide a process of a wavelength tuning carried with the use of substantially every embodiment of the laser source discussed above. Such process includes the steps of (1) outcoupling a portion of a first intracavity optical field, which has penetrated through the multiple layers at the first tilt angle within the first optical resonator and that has interacted with the third optical reflector, through a chosen optical reflector of the first and second optical reflectors in a form of a first laser light output, and (2) upon repositioning and/or reorienting at least the chosen optical reflector with respect to said multiple layers, forming a second intracavity optical field that propagates through the multiple layers at the second tilt angle. Here, the first laser light output has a first central wavelength. Alternatively or in addition—and substantially in every implementation, the method may be configured to satisfy at least one of the following conditions: (a) the method further includes propagating said first intracavity optical field through a free-space region prior to the outcoupling a portion of the first intracavity optical field; (b) the method is devoid of (that is, does not include) propagating the first intracavity optical field through a gap formed between the multiple layers and the third reflector; and (c) the method further includes mode-locking the first laser light output by propagating the first intracavity optical field through a semiconductor saturable absorber mirror element, a self-phase modulation Kerr lens element, and an active modulation element. In at least one case, the free-space region may be formed between the chosen optical reflector and the gain medium. Alternatively or in addition—and substantially in every implementation—the method may include a step of transmitting a portion of the second intracavity optical field that has interacted with the third optical reflector through the chosen optical reflector in a form of a second laser light output that has a second central wavelength. (Here, the first and second central wavelengths are different from one another.) In at least one specific case, the laser source may be structured to additionally include a fourth optical reflector and a fifth optical reflector that are optically connected through both the gain medium and the third optical reflector to define a third optical resonator that contains the gain medium. In this case, the method may additionally include one of the following steps: (i) generating simultaneously the first laser light output and a third laser light output that has a third central wavelength and that corresponds to the third optical resonator, and (i) generating simultaneously the second laser light output and the third laser light output. Optionally-when the fourth and fifth optical reflectors are present in the laser source—the method may also include the step of varying the third central wavelength by repositioning and/or reorienting at least one of the fourth optical reflector and the fifth optical reflector while maintaining an optical length of the third optical resonator substantially unchanged.

Embodiments further provide a laser source that includes a spatially-periodic multilayer material stack containing (i) a first material layer (characterized by an intrinsic electromagnetic resonance bandwidth) and a second material layer comprising a dielectric material; (ii) a first reflector of electromagnetic radiation having a first reflector axis that is tilted with respect to a first plane of a layer of the multilayer material stack; and (iii) a second reflector of the electromagnetic radiation having a second reflector axis that is tilted with respect to the first plane. Here, each of the first and second axes is in a second plane that is transverse to the first plane, and at least one of the first and second reflectors is separated from the spatially-periodic multilayer material stack with a gap. Optionally, the laser source may include a third reflector of electromagnetic radiation that is separated from each of the first and second reflectors by the multilayer material stack. (In this special case, the third reflector may be in contact with the gain medium or may be configured to be a part of the gain medium itself.) Optionally, substantially every embodiment of the laser source may be configured to satisfy at least one of the following conditions: (1) a combination of the first, second, and third reflectors defines an electromagnetic radiation resonant cavity limiting a path of electromagnetic radiation within such resonant cavity through the stack, the electromagnetic radiation path having first and second path portions each of which is tilted with respect to the first plane, and (ii) at least one of the first and second reflectors is configured to be spatially repositionable in the second plane such as to maintain an overall length of the path of electromagnetic radiation within said resonant cavity substantially constant and/or to maintain each of the first and second path portions substantially equally tilted with respect to the first plane. The multilayer stack may be configured as a gain medium (while the intrinsic electromagnetic resonance bandwidth is a bandwidth of a gain spectrum of the gain medium and while each of the first and second path portions of the path of the electromagnetic radiation within the resonant cavity traverses said gain medium. Alternatively or in addition, and substantially in every implementation, the laser source may be configured to define a first optical resonator having a first resonator axis and incorporating the material therein when the first reflector is in a first initial position and the second reflector is in a second initial position, and configured to define a second optical resonator having a second resonator axis and incorporating the spatially-periodic multiplayer material stack therein when the first reflector is in a first changed position and the second reflector is in a second changed position. (In such special case, the laser source may be configured to transform the first optical resonator into the second optical resonator by repositioning the first and second reflectors.) Optionally, an embodiment of the laser source may be configured to operate, as a VECSEL that has multiple spectral channels, in either of (a) a continuous-wave regime and (b) a pulsed regime, while each of the multiple spectral channels has a corresponding central wavelength and a corresponding spectral bandwidth that is narrower than the intrinsic electromagnetic resonance bandwidth.

### BRIEF DESCRIPTION OF THE DRAWINGS

The following disclosure will be better understood in reference to the following accompanying generally not-to-scale Drawings, of which:

FIGS. 1A, 1B illustrate schematically the conventional arrangement of the target material structure within a linear optical cavity (FIG. 1A) and an arrangement of the target material structure within a V-cavity (FIG. 1B).

FIG. 2A illustrates an experimental laser source that includes two coupled co-mode-locked VECSEL cavities, each limited by a corresponding output coupler (OC) and the semiconductor saturable absorber mirror (SESAM): the outer cavity 204, and the inner cavity 208. The pump energy 212 (delivered to the gain medium of the laser source from the pump source 216 is also partially illustrated. The cavities 204, 204 share the common VECSEL Gain medium (gain chip) 220. The SESAMs have 1 QW and the gain chip 220 has 10 QWs each with a respective distributed Bragg reflector (DBR).

FIG. 2B is a schematic representation of FIG. 2A, where inner cavity 204 is characterized by a tilt angle of about 21° and outer cavity 208 by a tilt angle of about 44°.

FIG. 3A: Autocorrelation traces characterizing mode-locked inner and outer V-cavities of a dual-V-cavity laser source structured according to the idea of the invention. The autocorrelation was taken on an FR-103 autocorrelator. One can see the pulses from both the inner and outer cavities.

FIG. 3B illustrates spectral shift due to co-modelocking frequency pulling. Thicker lines denote simultaneous operation of the two cavities, whereas thinner lines represent independent operation of the cavities.

FIGS. 4A and 4B provide illustration to the process of simulation of the operation of the laser source containing two coupled V-cavities. FIG. 4A provides an example of 2QW stack, where basic unit cells are shown for simulating an RPG QW stack and solving the SBEs which couple to the intermediate material-filled regions by sourcing Maxwell's Equations. FIG. 4B illustrates electromagnetic fields in grating basis are depicted, where one field qj interacts with a grating formed by two other fields (in-plane, not shown) along x\hat{ } scat within the QW.

FIG. 5A: Solid line comes from maximum coherence amplitude, where simulation is the result from microscopic simulations of single VECSEL V-Cavities. Dual V (Exp) represents the experimental results. Single V (Exp) are results for independent V-Cavities in setting up the Dual-V experiment.

FIG. 5B: The optical spectra of optical pulses obtained with the microscopic simulations.

FIG. 6A: Simulated dual cavity pulse waveforms, where Δϕ is depicted.

FIG. 6B: Corresponding dual kinetic hole burning in carrier distribution, a is red shifted from kinetic hole β.

Generally, the sizes and relative scales of elements in Drawings may be set to be different from actual ones to appropriately facilitate simplicity, clarity, and understanding of the Drawings. For the same reason, not all elements present in one Drawing may necessarily be shown in another.

### DETAILED DESCRIPTION

The developments discussed below demonstrate that the axial interference of the optical waves propagating off-axis through the host spatially-periodic bulk semiconductor medium (that is, at a chosen angle with respect to the normal drawn to the layers of such medium) can produce the chosen-angle-dependent spectral filtering of the typically broad gain of such host bulk 3D semiconductor medium. In particular, when the VECSEL laser source is configured, with the use of the target material structure, such that optical radiation is generated in the form of multiple optical beams propagating at different angles through the target material structure, such multiple optical beams serve to extract (and/or be fed with) narrow gain spectral subsets from (of) a broad gain line shape, thereby resulting in operationally independent multiple CW or mode-locked laser light outputs that share/originate in the same single RPG chip.

In particular, the implementation of the idea of the invention provides a solution to a problem of generation of trains of pulses of light characterized by a high degree of phase coherence (which trains of pulses are required for spectroscopic measurements at multiple wavelengths) without the use of an active stabilization technique. As discussed below, the solution to such problem is achieved by devising a multi-optical-cavity laser source that is configured to include multiple (in a specific non-limiting example discussed below-two) V-shaped optical cavities that are optically coupled with one another and that share the gain medium to cause the laser source to lase at multiple central wavelengths each of which respectively-corresponds to a corresponding of such multiple V-shaped optical cavities.

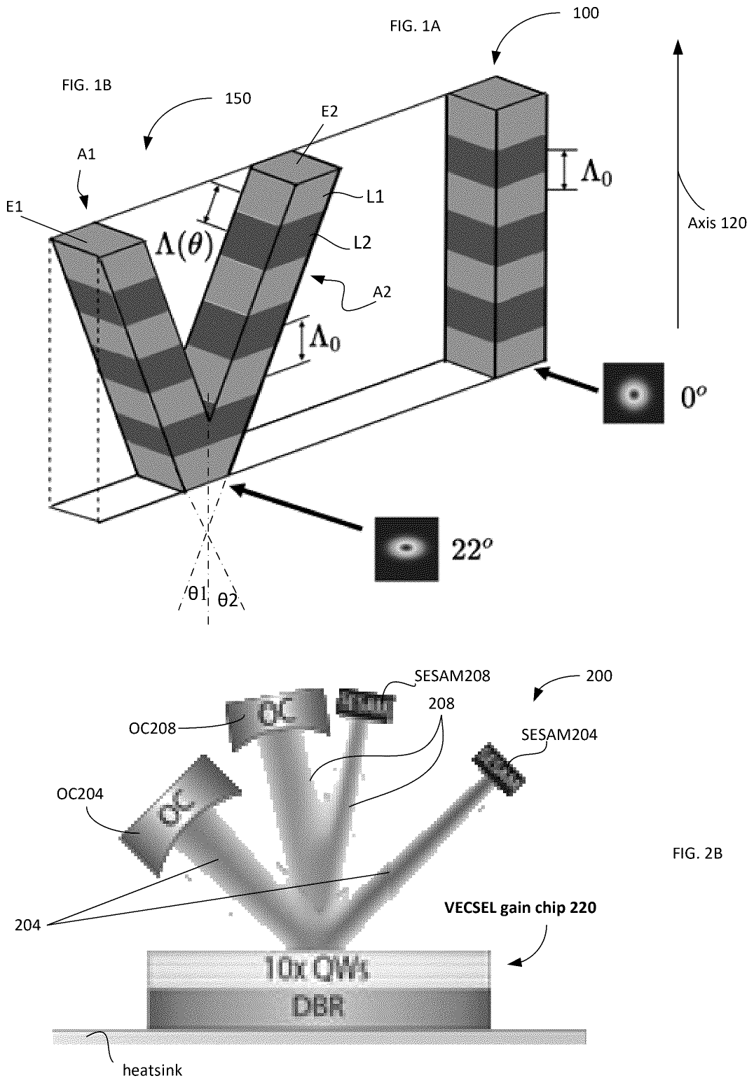

A schematic representation of spatial distribution of contents of what is conventionally understood by a V-shaped cavity-here, shown in the form of a spatially-periodic multilayer structure 150 including multiple alternating layers L1, L2 of corresponding semiconductor media arranged along two arms A1, A2 each of which is inclined at a corresponding tilt angle θ1, θ2 with respect to the axis 120 that is defined to be substantially normal to the layers L1, L2. (In the example of FIG. 1B, the absolute value of each of tilt angles θ1, θ2 is substantially equal to 22 degrees, as shown, but it is understood that the absolute value of a given angle can be different and/or the angles θ1, θ2 are not necessarily equal.) The outermost reflectors limiting the overall length of the V-cavity and forming the resonator containing the structure 150, each of which is positioned opposite to and directly optically coupled with the corresponding end E1, E2 of the material structure 150, are not shown for the simplicity of illustration. As a skilled artisan will readily appreciate, an additional (intermediate) reflector may be required (not shown) to redirect the radiation circulating withing the V-cavity from one of the arms A1, A2 to another. The inset to FIG. 1B illustrates the cross-section of an example of a modal distribution of light generated by the VECSEL laser source with the gain medium configured according to the structure 150.

As the skilled artisan will appreciate from the discussion below and according to the idea of the invention, the tuning of the spectral characteristic(s) of the light output of the laser source containing at least one optical V-cavity cavity (the contents/gain medium of which is/are spatially arranged according to the geometry depicted in FIG. 1B) is achieved by varying at least one of the angles θ1, θ2 using the change of the geometry of an external laser cavity within which the structure 150 is placed. Such process may be interchangeably referred to herein as an angular spectral tuning (or just angular tuning, for short).

The relationship between such angular tuning of axial periodically structured arrays/emitters/absorbers and the resultant spatial filtering action to extract a narrow spectral band from an otherwise much broader overall semiconductor gain/absorption profile has been demonstrated. Notably, such angular dependent wavelength extraction applies broadly to substantially any periodic axial arrangement of material structures of emitter/absorbers. A case in point might be, for example, a periodic arrangement of quasi-2D transition metal dichalcogenides (TMDC) monolayers separated by a distance substantially equal to a wavelength of light of the incident beam. Referring again to FIG. 1B, a single geometry multicolor resonant coherent source can be designed via the following relation:

$$Λ ( θ ) = \frac{{Λ}_{0}}{cos {θ}_{medium}}$$

This can be extended this to include the refractive index via Snell's Law:

$$Λ ( θ ) = \frac{{Λ}_{0}}{cos ( arcsin ( \frac{{n}_{0}}{{n}_{1}} sin θ ) )}$$

Here, no refers to the refractive index outside of the target material structure and n₁ refers to refractive index in the stack medium, and Λ₀ refers to the spacing of the periodic multilayer structure formed by the pre-determined semiconductor material in the 3D host semiconductor medium, and Λ(θ) refers to the periodic structure spacing at some chosen tilt angle θ (of which θ1, θ2 are two examples). The resonant coherent wavelength is related to the periodic structure spacing (Λ(θ)) via the following relation: λᵣₑₛ=2n₁Λ(θ).

### Examples of a Laser Source Configuration

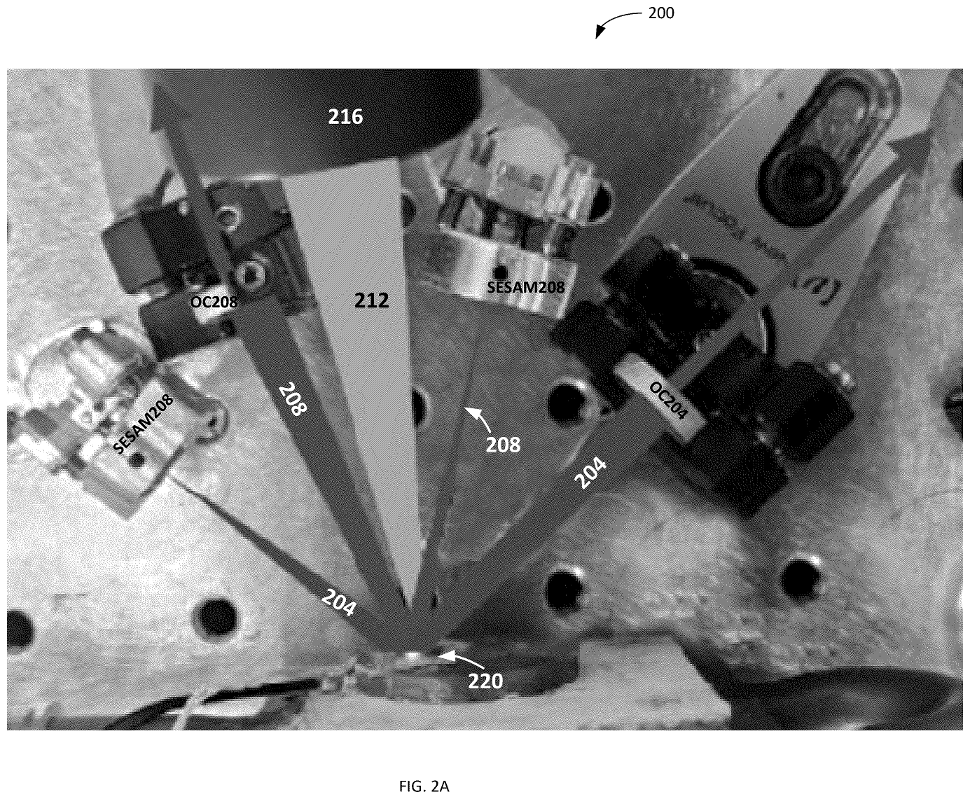

FIGS. 2A, 2B illustrate an example of an experimental layout and a schematic of the two co-modelocked laser V-cavities coupled with one another vis the gain medium that these cavities share, according to the idea of the invention. The cavity geometry chosen is the V-Cavity configuration, which is known to be practically simple and operationally robust. Each of the V-cavities, 204, 208 includes a corresponding SESAM (SESAM204, SESAM 208, respectively), a 0.6% curved output coupler (OC204, OC208 respectively), and a shared VECSEL resonant periodic gain (RPG) chip 220 of a gain medium and a shared intermediate reflector (here illustrated as the DBR). The chip 220 was designed to operate at around 1028 nm, in one example, at normal incidence. The lasing wavelength increases as a function of a tilt angle, as a consequence of the effective QW spacing that increases as the tilt angle between the arms of a given V-cavity increases. In developing a co-mode-locked dual cavity VECSEL laser source, the selection of a SESAM with proper characteristics was found to be rather important: the SESAM of a given V-cavity has to operate across a relatively large continuous spectral bandwidth and have a relatively short carrier lifetime. The cavities 204, 208 had adjustable lengths, which in one case could be chosen to be substantially equal (in one example—or about 6.2 cm, which corresponded to the optical pathlength of a laser pulse round trip within the cavities).

Notably, while in the example of FIGS. 2A, 2B the functions of a mode-lock element and a reflector are combined—by configuring each of SESAM204, SESAM208 as a semiconductor saturable absorber mirror—generally, a given V-cavity of an embodiment of the laser source (in the example of FIGS. 2A, 2B: either of the cavities 204, 208) may include at least one mode-lock element that is spatially distinct from each of the reflectors forming the cavity and that is disposed in optical communication with the gain medium and is configured to define mode-locked pulses of laser radiation generated inside a corresponding of the first and second optical resonators when said pump energy is delivered to the gain medium. In one non-limiting example, such spatially-distinct from a reflector mode-lock element may include a self-phase modulation Kerr lens element and/or an active modulation element.

As illustrated, the outermost reflectors (OC204, SESAM204) and (OC208, SESAM208) form what is known in the art as external laser cavities. Generally, both the spatial locations and spatial orientations of the outermost reflectors in each of the V-cavities of the laser source 200—the reflectors (OC204, SESAM204) and the reflectors (OC208, SESAM208)—may be variable: the laser source 200 is generally configured to allow for variation of a tilt angle of an arm of a constituent V-cavity (as defined above). In at least one specific case, when such variation is implemented, the optical length of the constituent V-cavity in question may be maintained unchanged.

A person of skill in the art will readily appreciate that, in a simplified version of the laser source structured according to the idea of the invention, there may be present only one, single constituent V-cavity at least partially filled with the gain medium structured as the medium 150 of FIG. 1B. The outermost reflectors of such single-V-cavity laser source—the corresponding OC and SESAM, for example—may also be configured to be spatially repositionable and reorientable such as (i) to define a V-cavity characterized by a first set of arms tilted with respect to the normal (drawn to the surfaces of the multilayer structure 150 of FIG. 1B and represented by the axis 120 of FIGS. 1A, 1B) at a first set of tilt angles when these outermost reflectors are in their initial positions and/or orientations, and (ii) to define a changed V-cavity characterized by a second set of arms tilted with respect to the same normal at a second set of tilt angles when these outermost reflectors are in their change positions and/or orientations. At the same time, a more complex laser source can be devised containing more than two of V-cavities coupled through using the same gain medium-in this case, lasing in each of the cavities will be generated at a corresponding central wavelength.

As a skilled artisan will readily appreciate, regardless of the specifics of implementation of a laser source according to the idea of the invention-that is, regardless of whether the laser source includes a single pair of outermost reflectors limiting a V-cavity or multiple pairs of outermost reflectors limiting respectively corresponding multiple coupled with one another at least through one intermediate reflector V-cavities-such implementation, when utilizing a gain medium that includes a stack of spatially-periodic material layers, is preferably configured to generate a standing optical wave within the gain medium such that the standing optical wave has antinodes that are located at the substantially periodically spaced multiple layers.

Accordingly, an implementation of a laser source the invention manifests in a device that includes at least a gain medium (that has a gain spectrum characterized by a gain spectrum bandwidth and that includes multiple layers of substantially periodically spaced layers of a chosen semiconductor material) and an optical apparatus including at least a first optical reflector, a second optical reflector, and a third optical reflector. Such optical apparatus is configured to define a first optical resonator having a first resonator axis and incorporating the gain medium therein when the first optical reflector is in a first initial position and the second optical reflector is in a second initial position. Additionally, such optical apparatus is configured to define a second optical resonator having a second resonator axis and incorporating the gain medium therein when the first optical reflector is in a first changed position and the second optical reflector is in a second changed position. Each of the first and second optical resonators share the third reflector. The first resonator axis is tilted with respect to a normal drawn to the multiple layers by a first angle while the second resonator axis is tilted with respect to this normal by a second angle that is different from the first angle. At least optionally, at least one of the following conditions may be satisfied: the third optical reflector is separated from each of the first and second optical reflectors by said gain medium; the third optical reflector is in contact with or comprises a part of said gain medium; at least one of the first and second optical reflectors is separated from the gain medium with a corresponding gap; the at least one of the first and second optical reflectors is substantially perpendicular to a corresponding axis of the first and second resonator axes. As a skilled person will readily appreciate, considering the spatially-periodic multilayered nature of the gain medium 150 within a given V-cavity of the chosen version of the laser source, the corresponding laser source may be configured to generate a first standing optical wave within the gain medium when the first, second, and third optical reflectors form the first optical resonator (such first standing optical wave characterized by having its antinodes that are located at the substantially periodically spaced multiple layers) and to generate a second standing optical wave within the gain medium when the first, second, and third optical reflectors form the second optical resonator (such the second standing optical wave also characterized by having its antinodes located at the substantially periodically spaced multiple layers).

### Experimental Results

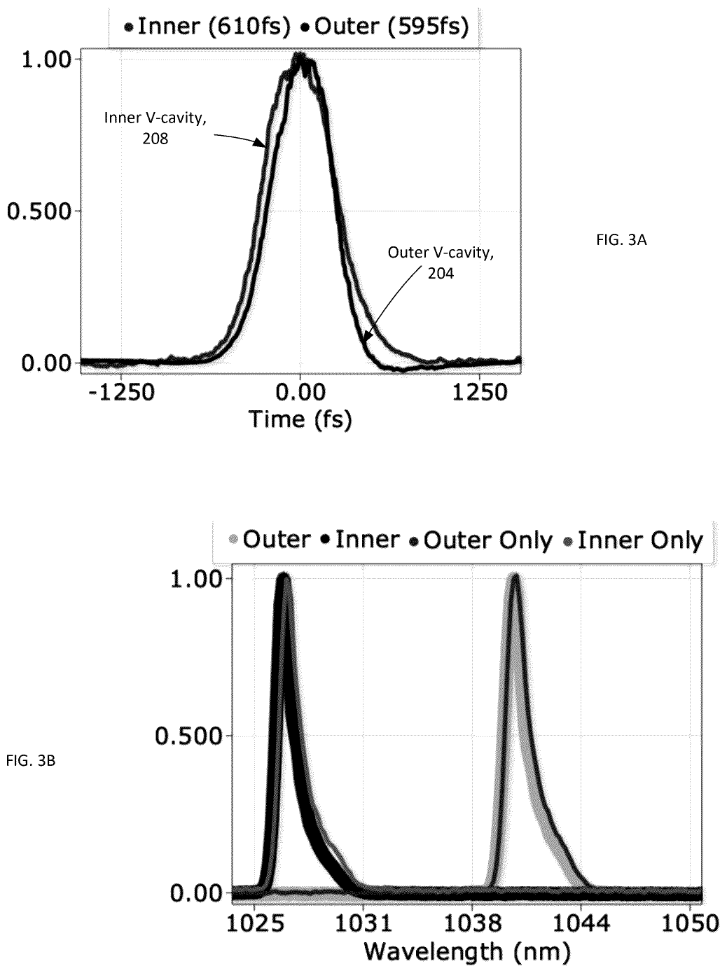

Referring now to the embodiment of FIGS. 2A, 2B, the mode-locking of dual V-cavities of the laser source mode-locking was successfully demonstrated for different cavity angles. Autocorrelation traces for stable mode-locked operation of each of the inner and outer V-cavities are shown in FIG. 3A. The autocorrelator used sum-frequency x2 nonlinear process to measure the pulse envelope as shown in FIG. 2. The average power for the inner cavity was 28 mW and that for the outer cavity was 32 mW, with widths of generated pulses of light of about 610 fs and about 595 fs, respectively. The pulse repetition rates were measured for the inner and outer cavities to be 2.11 GHz and 2.17 GHz, respectively.

This co-modelocked VECSEL system is stably modelocked on two well-define and spectrally-separated from one another wavelengths (each being a central wavelength of light generation within the corresponding of the two constituent V-cavities) due to low level pulse interaction. The low pulse cross-talk was verified by blocking the respective V-cavity arms and measuring the shift in the spectral response (as illustrated in FIG. 3B). This effect was attributed to extraction of light from within two separate spectral windows within the full gain bandwidth of the gain medium, as will be discussed below. Understandably, more spectral channels can be implemented by adding more V-cavities to the structure of FIGS. 2A, 2B.

### Simulation of Operation of a Laser Source Containing Multiple Coupled V-Cavities.

The following discussion is presented for the non-limiting case of the laser source system of FIGS. 2A, 2B, where the embodiment of the laser source is configured to have two coupled (external) V-cavities.

The Maxwell-Semiconductor Bloch Equations (SBEs) represent a microscopic first principles many-body approach essential to uncovering ultrafast pulse dynamics on timescales comparable to typical dephasing times thereby supplanting traditional “gain”-based methods. In ultrafast systems, carrier distributions are driven into extreme non-equilibrium states, a situation not observable in the gain that integrates over such distributions. The operation of the ultrafast systems involves many-body Coulomb interactions that influence dynamic bandgap reduction through energy and also field renormalization (Hartree-Fock level), carrier-carrier and carrier-phonon scattering. The latter two have been shown to be adequately captured in terms of a microscopically derived dual rate approximation. The damping rates described below (see, for example, A. Bäumner, S. W. Koch, and J. V. Moloney, Physica Status Solidi (b), 248, 843, 2011) are summarized with the following notation: I depth (po-larization dephasing), Γ_{scatt} (slow charge carrier recovery time), Γ_{fill} (fast charge carrier recovery time), and Λₛₚₒₙₜ (spontaneous emission noise). The renormalized Rabi energy appearing in the Ωk terms below is defined by

$$d \cdot E + {\sum }_{{k}^{′}} {V}_{k - {k}^{′}} {p}_{k}^{′} ,$$

where d is the dipole matrix element between the conduction and valence bands and V is the screened Coulomb matrix element. The renormalized carrier frequency appears as the ωₖ, which is defined as

$$\frac{1}{ℏ} [ {ϵ}_{k} - {\sum }_{{k}^{′}} {V}_{k - {k}^{′}} ( {n}_{{k}^{′}}^{c} + {n}_{{k}^{′}}^{h} ) ] : \qquad ( 1 )$$

$$\frac{\partial }{\partial t} {p}_{k} = - i {ω}_{k} {p}_{k} - i {Ω}_{k} ( {n}_{k}^{e} + {n}_{k}^{h} - 1 ) + {Γ}_{deph} + {Λ}_{spont}^{p}$$

$$\frac{\partial }{\partial t} {n}_{k}^{e / h} = i ( {Ω}_{k} {p}_{k}^{*} - {Ω}_{k}^{*} {p}_{k} ) + {Γ}_{scatt} + {Λ}_{spont}^{n} + {Γ}_{fill}$$

$${Γ}_{deph} = - \frac{1}{{τ}_{deph}} {p}_{k} , {Γ}_{scatt} = - \frac{1}{{τ}_{scatt}} ( {n}_{k}^{e / h} - {f}_{k}^{e / h} )$$

$${Γ}_{fill} = - \frac{1}{{τ}_{fill}} ( {n}_{k}^{e / h} - {F}_{k}^{e / h} )$$

$${Λ}_{spont}^{e / h} = β \frac{{n}_{bg}^{3}}{{π}^{2} {ϵℏ}^{4} {c}_{0}^{3}} {\vert {d}_{k}^{cv} \vert}^{2} {( {E}_{g} + \frac{{ℏ}^{2} {k}^{2}}{2 {m}_{r}} )}^{3} {n}_{k}^{c} {n}_{k}^{h} .$$

The macroscopic polarization driving the electric field within each cavity is given by:

∫d_{cv}·pₖkdk, which sources Maxwell's equations:

$$( {\partial }_{zz} - \frac{{n}^{2}}{{c}^{2}} {\partial }_{n} ) E ( z , t ) = {μ}_{0} {\partial }_{n} P ( z , t ) . \qquad ( 2 )$$

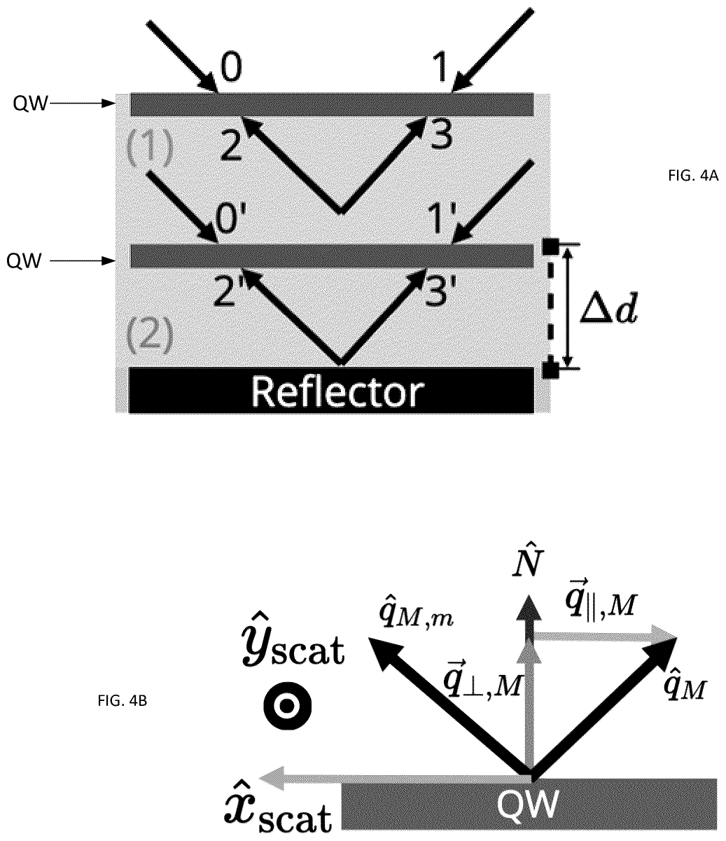

In analyzing the field dynamics within the coupled V-cavity, the Fourier expansion approach of Lindberg et. al. (see M. Lindberg, R. Binder, and S. W. Koch, Phys. Rev. A 45, 1865,1992) was extended beyond a paraxial assumption to account for large incident beam angles. In the case of Lindberg et. Al., these modes were developed as an infinite sum of paraxial interference terms imparting a transverse grating across the gain chip. To account for arbitrary angles of incidence, we introduced a wide-angle grating basis, which naturally truncates due to evanescent coupling to the surface of the gain chip (see FIG. 4B). Details of this wide-angle grating expansion and its numerical implementation will be discussed in more detail elsewhere. In contrast to an individual V-cavity, where the total intracavity field can be broken down to two bidirectional interfering beams (˜ a 4-beam interference), the current situation involves 4 bidirectional beams within the dual V-cavity system. This yields a large hierarchy of interference terms from the 8-beam interference within both coupled cavities. The experimental observation described above that both mode-locked channels operate substantially independently justifies the neglect of many higher order cross-interference terms. Consequently, it was assumed that constituent multiple V-cavities of the laser source couple solely through the carrier distributions within the common gain chip 220. In this limit, the microscopic polarization expansion takes the simpler form of

$${p}_{k} = {\sum }_{M} {\sum }_{m} {p}_{k , M , m} {e}^{i {\hat{q}}_{M , m} \cdot \vec{R}} , \qquad ( 3 )$$

where in the co-planar case one can calculate the transverse Fourier wavenumber to be:

$${\hat{q}}_{M , m} = ( 1 + 2 m ) {\vec{q}}_{‖ , M} + \sqrt{1 - {\vert {\vec{q}}_{‖ , M} \vert}^{2} {( 1 + 2 m )}^{2}} \hat{N} . \qquad ( 4 )$$

Likewise, one can use the same expansion to calculate the carrier population terms:

$${n}_{k} = {\sum }_{M} {\sum }_{{M}^{′}} {\sum }_{n , m} {n}_{k , m , n} {e}^{j {\hat{G}}_{M , {M}^{′}} ( m , n ) \cdot \vec{R}} , \qquad ( 5 )$$

Here, the function G is expressed as

$${\vec{G}}_{M , {M}^{′}} ( n , m ) = 2 ( m {\vec{q}}_{‖ , M} - n {\vec{q}}_{‖ , {M}^{′}} ) + ( \sqrt{1 - {( 1 + 2 m )}^{2} {\vec{q}}_{‖ , M}^{2}} - \sqrt{1 - {( 1 + 2 n )}^{2} {\vec{q}}_{‖ , {M}^{′}}^{2}} ) \hat{N} . \qquad ( 6 )$$

The lower-case integer notation (m,m′) was employed to refer to a Fourier mode and the capital-case integer notation (M,M′) was employed to denote individual fields within the stencil shown in FIGS. 4A, 4B. The greatest benefit of utilizing the grating basis is the naturally induced cutoff for the interference terms, which limits the extent of m to be

$${m}_{limit} = \frac{1}{2} ( \pm \frac{1}{sin θ} - 1 )$$

This provided a natural cutoff for higher-order interference terms, allowing for more efficient parallelization and simulation. In the above equations (see FIG. 4B)), the vector \vec{q}_{∥,M} represents the component of the propagation vector of beam M which interacts with the grating along the QW. Each beam then generates diffracted beams from the grating, which are denoted as \hat{q}_{M,m}. \vec{G}_{M,M′}(n,m) is an un-normalized vector in Eq. 6 encoding the interference along the surface of the QW of two beams, M and M′.

The RPG structure is represented by a periodic stack of QWs with spacer layers and the SESAMs, a single QW with spacer layer. The stencil shown in FIGS. 4A, 4B is the elemental building block implemented at each QW, adjoining spacer layer and replicated throughout the dual cavity geometry to form the complete simulation framework (the details of which will be discussed elsewhere).

Finally, a group delay dispersion (GDD) was introduced into the simulation framework to account for intrinsic dispersion arising from gain chip, SESAM, and other cavity components. These data were available from the experiment and was responsible for the relatively long pulse durations observed in FIGS. 3A, 3B. The effect produced by the GDD was a quadratic dependence of phase from frequency in the spectral domain:

$${ϕ}_{GDD} = \frac{{GDD}_{ω}}{2} {( ω - {ω}_{0} )}^{2} \qquad ( 7 )$$

and can be applied as follows (F denotes the operation of the Fourier transform):

$${E}^{′} ( z , t ) = \{ \{ E ( z , t ) \} {e}^{i {ϕ}_{GDD}} \} . \qquad ( 8 )$$

Lastly, in order to solve these coupled sets of integro-differential equations, the Runge-Kutta 4 (RK4) methodology known in the art was employed to calculate system dynamics.

### Simulation Results

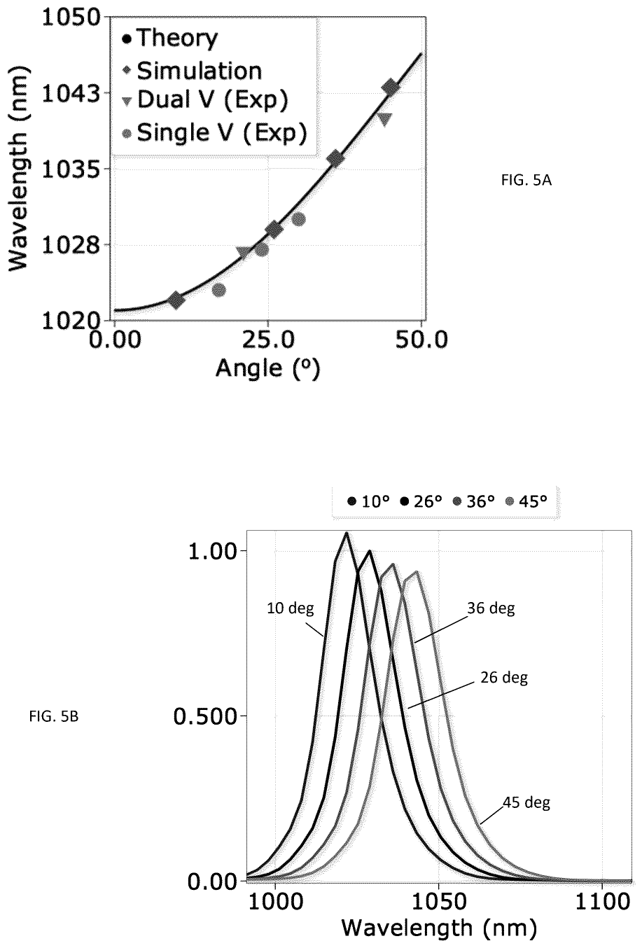

Having the benefit of the discussion presented so far, a skilled artisan can now infer that the lasing emission should be tilt-angle dependent, from a consideration of the partial coherence of a periodic array of emitters corresponding to the 10 QW RPG stack as shown in FIG. 5A. The solid line in FIG. 5A is the analytic prediction for a set of periodic emitters, the diamonds show results from numerical simulation data from the single V-Cavity Maxwell-SBE models, the triangles represent actual experimental results (shown in FIG. 5B), and the dots depict the results of independent single V-Cavity measurements with the same gain chip and SESAM. FIG. 5B displays the final filtered spectral bandwidths resulting from the single V-Cavity simulations lasing at different incident angles.

Next, the full dual cavity simulation was run for the inner cavity and the outer cavity tilt angles (of the system of FIGS. 2A, 2B), corresponding to those chosen in the above-described experiment. The cavity parameters-such as outcoupling loss, for example-had to be adjusted to balance intensities of mode-locked pulses of light in the dual wavelength channel. dual wavelength channel. The GDD of +100 frs was imposed, which lengthened the pulse durations to about 300 fs. The simulation was run for 1000 cavity roundtrips at which point stable mode-locking was well established. (The convergence of the process was accelerated by using week seed pulses rather that by allowing the buildup from noise.)

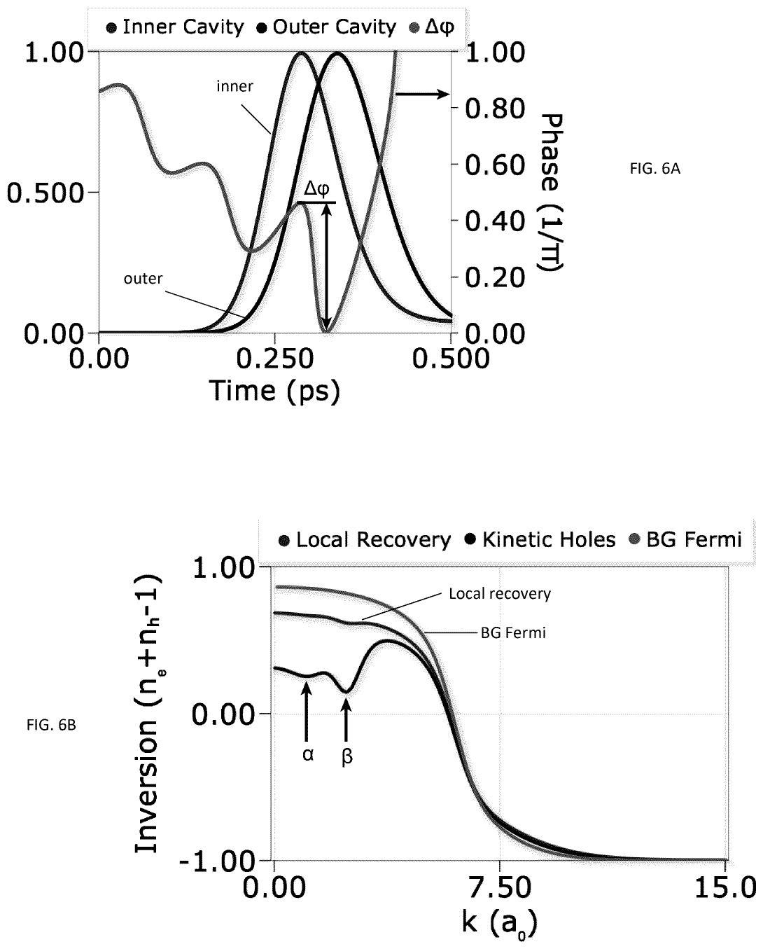

Despite deliberately offsetting the initial seed pulse relative spacing in each cavity we observe that pulses tend to bunch up, hitting the gain chip with a small relative delay as shown in FIG. 6A) in our limiting case where the two cavity lengths are substantially matched with one another (with the residual difference of about ΔL=1 μm). FIG. 6B), shows the nonequilibrium evolution of the carrier inversion, starting from the external pumped Fermi distribution BG Fermi. After hundreds of roundtrips, the pulses self-replicated indicating stable mode-locking. Dual kinetic holes with the same delay as the pulses on the left, were burned in the carrier inversion. Stable mode-locking was ensured as the inversion always remains positive. After each pulse, the carrier distribution recovered to a hot near-Fermi distribution. Notably, that the kinetic holes were not uniformly burned within each of the 10 QWs in the RPG stack.

The reason for the bunching of the mode-locked pulses within each V-cavity arm on the gain chip is not self-evident. One might argue that, because the individual pulses are extracting carriers from separate reservoirs, the net gain (integral over the distributions) reduction is larger leading to a larger transient cooling of the system. An alternative argument, that both pulses are attracted through mutual phase locking, is supported by the relative phase jump between both pulses, as plotted in FIG. 6A). There is a significant body of evidence in the related art for soliton attraction through phase locking and that this locking is evident from an approximate Δϕ=π jump in the phase between both pulses. Gagnon et al. (L. Gagnon and N. Stiévenart, Opt. Lett. 19, 619, 1994) argue that mutual attraction will occur if the phase deviates from Δϕ=π. Even more compelling experimental evidence (P. Grelu, et al., J. Opt. Soc. Am. B 20, 863, 2003) on modelocked, phase-locked systems in ring fiber cavities support that this phase should slightly deviate from this π especially as pulses maintain closer distances to each other. Grelu et al. demonstrate two pulses within 2.739 ps of each other and measured the phase difference of the pulses to be ≅0.483, with 1e-3 radian phase measurement accuracy. (In the current work, the simulated pulses were within 36 fs of each other with a maximum phase shift measured to be ≅0.462π.)

It has been unexpectedly discovered that the method for generating laser output with the use of a device incorporating a V-shaped optical cavity containing the target material structure at different V-cavity angles provides the relationship for the expected lasing wavelength substantially without coherent frequency pulling. The effect of Coherent Frequency Pulling is an intrinsic part of the resonant semiconductor gain/refractive index and adjusts the wavelength to the cavity resonance. The interference of optical waves in the material stack of the target material structure can also be used to describe the bandwidth limit of a particular set of elements. The central wavelength of light generated with the use of the device at two different V-cavity angles is increased with increase of the angle of V-cavity, which allows one to selectively tune the coherence wavelength of a coherence stack.

For the purposes of this disclosure and the appended claims, the use of the terms “substantially”, “approximately”, “about” and similar terms in reference to a descriptor of a value, element, property or characteristic at hand is intended to emphasize that the value, element, property, or characteristic referred to, while not necessarily being exactly as stated, would nevertheless be considered, for practical purposes, as stated by a person of skill in the art. These terms, as applied to a specified characteristic or quality descriptor means “mostly”, “mainly”, “considerably”, “by and large”, “essentially”, “to great or significant extent”, “largely but not necessarily wholly the same” such as to reasonably denote language of approximation and describe the specified characteristic or descriptor so that its scope would be understood by a person of ordinary skill in the art. In one specific case, the terms “approximately”, “substantially”, and “about”, when used in reference to a numerical value, represent a range of plus or minus 20% with respect to the specified value, more preferably plus or minus 10%, even more preferably plus or minus 5%, most preferably plus or minus 2% with respect to the specified value. As a non-limiting example, two values being “substantially equal” to one another implies that the difference between the two values may be within the range of +/−20% of the value itself, preferably within the +/−10% range of the value itself, more preferably within the range of +/−5% of the value itself, and even more preferably within the range of +/−2% or less of the value itself. The use of these terms in describing a chosen characteristic or concept neither implies nor provides any basis for indefiniteness and for adding a numerical limitation to the specified characteristic or descriptor. As understood by a skilled artisan, the practical deviation of the exact value or characteristic of such value, element, or property from that stated falls and may vary within a numerical range defined by an experimental measurement error that is typical when using a measurement method accepted in the art for such purposes.

The expression of the type “element A and/or element B” has the meaning intended to be equivalent to “at least one of element A and element B”.

Notably, embodiments of the invention include those containing substantially any substantially spatially periodic array of light emitting elements exhibiting gain; the pump of the gain medium can be configured to be electrical and/or optical; and electromagnetic cavity of an embodiment of the device configured as a linear cavity (with beams of electromagnetic radiation incident on the same gain medium at different angles) or a ring cavity is within the scope of the invention, provided the beam of the electromagnetic radiation oriented at an angle with respect to a spatially periodic stack of the gain medium material is used to tune a wavelength of light, generated in such medium within the resonant cavity within the limits of the full bandwidth of full gain afforded by the gain medium. While the invention is described through the above-described exemplary embodiments, it will be understood by those of ordinary skill in the art that modifications to, and variations of, the illustrated embodiments may be made without departing from the inventive concepts disclosed herein. Disclosed aspects, or portions of these aspects, may be combined in ways not listed above.

Whether expressly indicated in the drawings or not, operation of an embodiment of the laser source may involve the use of programmable processor: some of the steps of the embodiments of the method of the invention can be effectuated with a programmable processor (operably cooperated with at least one piece of hardware of a given embodiment; not shown in Figures for simplicity of illustration). The processor, if present, is controlled by instructions stored in a tangible, non-transitory storage memory. The memory may be random access memory (RAM), read-only memory (ROM), flash memory or any other memory, or combination thereof, suitable for storing control software or other instructions and data. Some of the functions performed by the processor have been described with reference to flowcharts and/or block diagrams. Those skilled in the art should readily appreciate that functions, operations, decisions, etc. of all or a portion of each block, or a combination of blocks, of the flowcharts or block diagrams may be implemented as computer program instructions, software, hardware, firmware, or combinations thereof. Those skilled in the art should also readily appreciate that instructions or programs defining the functions of the present invention may be delivered to a processor in many forms, including, but not limited to, information permanently stored on non-writable storage media (e.g. read-only memory devices within a computer, such as ROM, or devices readable by a computer I/O attachment, such as CD-ROM or DVD disks), information alterably stored on writable storage media (e.g. floppy disks, removable flash memory and hard drives) or information conveyed to a computer through communication media, including wired or wireless computer networks. In addition, while the invention may be embodied in software, the functions necessary to implement the invention may optionally or alternatively be embodied in part or in whole using firmware and/or hardware components, such as combinatorial logic, Application Specific Integrated Circuits (ASICs), Field-Programmable Gate Arrays (FPGAs) or other hardware or some combination of hardware, software and/or firmware components.

References throughout this specification to “one embodiment,” “an embodiment,” “a related embodiment,” or similar language mean that a particular feature, structure, or characteristic described in connection with the referred to “embodiment” is included in at least one embodiment of the present invention. Thus, appearances of the phrases “in one embodiment,” “in an embodiment,” and similar language throughout this specification may, but do not necessarily, all refer to the same embodiment. It is to be understood that no portion of disclosure, taken on its own and in possible connection with a figure, is intended to provide a complete description of all features of the invention. Within this specification, embodiments have been described in a way that enables a clear and concise specification to be written, but it is intended and will be appreciated that embodiments may be variously combined or separated without parting from the scope of the invention. In particular, it will be appreciated that all features described herein are applicable to all aspects of the invention.

When the present disclosure describes features of embodiments of the invention with reference to corresponding drawings (in which like numbers represent the same or similar elements, wherever possible), the depicted structural elements are generally not to scale, and certain components may be enlarged or reduced in size relative to the other components for purposes of emphasis and understanding. It is to be understood that no single drawing is intended to support a complete description of all features of the invention. In other words, a given drawing is generally descriptive of only some, and generally not all, features of the invention. A given drawing and an associated portion of the disclosure containing a description referencing such drawing do not, generally, contain all elements of a particular view or all features that can be presented is this view, at least for purposes of simplifying the given drawing and discussion, and directing the discussion to particular elements that are featured in this drawing. A skilled artisan will recognize that the invention may possibly be practiced without one or more of the specific features, elements, components, structures, details, or characteristics, or with the use of other methods, components, materials, and so forth. Therefore, although a particular detail of an embodiment of the invention may not be necessarily shown in each and every drawing describing such embodiment, the presence of this particular detail in the drawing may be implied unless the context of the description requires otherwise. In other instances, well known structures, details, materials, or operations may be not shown in a given drawing or described in detail to avoid obscuring aspects of an embodiment of the invention that are being discussed. Furthermore, the described single features, structures, or characteristics of the invention may be combined in any suitable manner in one or more further embodiments.

1. A laser source comprising:
a gain medium having a gain spectrum characterized by a gain spectrum bandwidth, said gain medium including multiple layers of substantially periodically spaced layers of a chosen semiconductor material; and
an optical apparatus including at least a first optical reflector, a second optical reflector, and a third optical reflector, said optical apparatus configured to define:
a first optical resonator having a first resonator axis and incorporating the gain medium therein when the first optical reflector is in a first initial position and the second optical reflector is in a second initial position, and
a second optical resonator having a second resonator axis and incorporating the gain medium therein when at least one of the first optical reflector and the second optical reflector is in a corresponding changed position,
wherein the first and second optical resonators share the third reflector, and
wherein the first resonator axis is tilted with respect to a normal drawn to said multiple layers by a first tilt angle while the second optical axis is tilted with respect to said normal by a second tilt angle that is different from the first tilt angle.

2. A laser source according to claim 1, further comprising a pump source in operable communication with the gain medium and configured to pump energy to the gain medium to produce excited-state carriers in the chosen semiconductor material.

3. A device according to claim 1, wherein at least one of the following conditions is satisfied:
(3A) a first optical cavity length of the first optical resonator is substantially equal to a second optical cavity length of the second optical resonator; and
(3B) the second optical resonator includes both the first optical reflector in a first changed position and the second optical reflector in a second changed position.

4. A device according to claim 1, wherein at least one of the following conditions is satisfied:
the third optical reflector is separated from each of the first and second optical reflectors by said gain medium;
the third optical reflector is in contact with or comprises a part of said gain medium;
at least one of the first and second optical reflectors is separated from the gain medium with a corresponding free-space gap;
the at least one of the first and second optical reflectors is substantially perpendicular to a corresponding axis of the first and second resonator axes; and
each of the first optical resonator and the second optical resonator is dimensioned to define a corresponding V-cavity of the laser source.

5. A laser source according to claim 1, wherein said multiple layers of the chosen semiconductor material are configured as quantum wells (QWs).

6. A laser source according to claim 1, dimensioned
to generate a first standing optical wave within said gain medium when the first, second, and third optical reflectors form the first optical resonator, wherein the first standing optical wave is characterized by first antinodes that are located at the substantially periodically spaced multiple layers, and
to generate a second standing optical wave within said gain medium when the first, second, and third optical reflectors form the second optical resonator, wherein the second standing optical wave is characterized by second antinodes located at the substantially periodically spaced multiple layers.

7. A laser source according to claim 1, further comprising
at least one mode-lock element disposed in optical communication with the gain medium and configured to define mode-locked pulses of laser radiation generated inside a corresponding of the first and second optical resonators when the gain medium is pumped.

8. A laser source according to claim 7, wherein the at least one mode-lock element comprises at least one of a semiconductor saturable absorber mirror element, a self-phase modulation Kerr lens element, and an active modulation element.

9. A laser source according to claim 1, wherein the optical apparatus is configured to transform the first optical resonator into the second optical resonator by repositioning and/or reorienting both the first optical reflector and the second optical reflector while maintaining optical lengths of the first and second optical resonators substantially equal.

10. A laser source according to claim 1, configured to operate, as a VECSEL that has multiple spectral channels, in either of (a) a continuous-wave regime and (b) a pulsed regime, wherein each of said multiple spectral channels has a corresponding central wavelength and a corresponding spectral bandwidth that is narrower than the gain spectrum bandwidth.

11. A laser source according to claim 10, wherein, when the laser source is configured to operate as said VESCEL in the pulsed regime, the laser source is configured to have a first repetition rate of pulses generated in a first of the multiple spectral channels be adjustable substantially independently from adjusting a second repetition rate of pulses generated in a second of the multiple spectral channels, wherein the first of the multiple spectral channels corresponds to the first optical resonator of said VECSEL and the second spectral channel corresponds to the second optical resonator of said VECSEL.

12. A laser source according to claim 1, further comprising a fourth optical reflector and a fifth optical reflector optically connected through the gain medium and the third optical reflector to define a third optical resonator, the laser source configured to simultaneously generate optical radiation at (i) one of a first central wavelength corresponding to the first optical resonator and at a second central wavelength corresponding to the second optical resonator, and (ii) a third central wavelength corresponding to the third optical resonator.

13. A laser source according to claim 1, wherein a first central wavelength corresponding to the first optical resonator is shorter than a second central wavelength corresponding to the second optical resonator when the first tilt angle is smaller than the second tilt angle.

14. A laser source according to claim 1, wherein said gain medium includes a layer of Transition Metal Dichalcogenide (TMDC) material.

15. A method comprising: with the use of the laser source according to claim 1, outcoupling a portion of a first intracavity optical field, which has penetrated through said multiple layers at the first tilt angle within the first optical resonator and that has interacted with the third optical reflector, through a chosen optical reflector of the first and second optical reflectors in a form of a first laser light output,
wherein the first laser light output has a first central wavelength;
and
upon repositioning at least said chosen optical reflector with respect to said multiple layers, forming a second intracavity optical field that propagates through said multiple layer at the second tilt angle.

16. A method according to claim 15, wherein at least one of the following conditions is satisfied:
(16A) the method further comprises propagating said first intracavity optical field through a free-space region prior to said outcoupling;
(16B) the method is devoid of propagating said first intracavity optical field through a gap formed between said multiple layers and the third reflector; and
(16C) the method further comprises mode-locking the first laser light output by propagating the first intracavity optical field through a semiconductor saturable absorber mirror element, a self-phase modulation Kerr lens element, and an active modulation element.

17. A method according to claim 16, wherein said free-space region is formed between the outcoupling optical reflector and the gain medium.

18. A method according to claim 15, further comprising:
outcoupling a portion of the second intracavity optical field that has interacted with the third optical reflector through the chosen optical reflector in a form of a second laser light output that has a second central wavelength, wherein the first and second central wavelengths are different from one another.

19. A method according to claim 15, wherein the laser source additionally includes a fourth optical reflector and a fifth optical reflector that optically connected through both the gain medium and the third optical reflector to define a third optical resonator containing said gain medium,
the method further comprising:
(19A) generating simultaneously the first laser light output and a third laser light output that has a third central wavelength and that corresponds to the third optical resonator, or
(19B) generating simultaneously the second laser light output and the third laser light output.

20. A method according to claim 19, further comprising:
varying the third central wavelength by repositioning and/or reorienting at least one of the fourth optical reflector and the fifth optical reflector while maintaining an optical length of the third optical resonator substantially unchanged.
